(19) United States
(12) Patent Application Publication
(10) Pub. No.: US 2016/0191013 A1
(43) Pub. Date: Jun. 30, 2016

(54) WAVE FILTER PACKAGES AND METHODS FOR MANUFACTURING THE SAME

(71) Applicant: SHUNSIN TECHNOLOGY (ZHONG SHAN) LIMITED, Zhongshan (CN)

(72) Inventor: JUN-YI XIAO, Shenzhen (CN)

(21) Appl. No.: 14/981,179

(22) Filed: Dec. 28, 2015

(30) Foreign Application Priority Data
Dec. 25, 2014 (CN) 201410819599.1

(51) Int. Cl. H03H 9/46; H03H 3/00

(52) U.S. Cl. CPC H03H 9/46; H03H 3/00

(57) ABSTRACT

A wave filter package and a method for manufacturing wave filter packages are presented. The wave filter package includes a chip, a substrate, and a sealed wall, the sealed wall being set up between the chip and the substrate so as to form a sealed chamber. The distance between the substrate and the chip is minimized, so that the height of the sealed wall can be decreased, thereby reducing the size of a wave filter package.

### FIELD

The present invention relates generally to wave control.

### BACKGROUND

Filters are reduced in their size, in order to meet the requirement in electronics industry that all electronic products are thinner and lighter.

### SUMMARY

In one aspect of the disclosure, a wave filter package includes a chip, a substrate and a sealed wall. The sealed wall is set up between the chip and the substrate so as to form a sealed chamber. The subject matter of this disclosure minimizes the dimensions of the substrate and the chip, so that the height of the sealed wall can be decreased, thereby reducing the size of a wave filter package.

### BRIEF DESCRIPTION OF THE DRAWINGS

The components in the drawings are not necessarily drawn to scale, the emphasis instead being placed upon clearly illustrating the principles of the present disclosure. Moreover, in the drawings, like reference numerals designate corresponding parts throughout several views.

FIG. 1 is a sectional view of a wave filter package.

FIG. 2 is a sectional view of the wave filter package shown in FIG. 1 between points A-A.

FIG. 3 is a flow chart of the method for manufacturing a wave filter package.

FIG. 4 is a diagram of the structure of the wave filter package in step S11 shown in FIG. 3.

FIG. 5 is a diagram of the structure of the wave filter package in step S12 shown in FIG. 3.

FIG. 6 is a diagram of the structure of the wave filter package in step S13 shown in FIG. 3.

FIG. 7 is a diagram of the structure of the wave filter package in step S14 shown in FIG. 3.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

The term “comprising,” when utilized, means “including, but not necessarily limited to”; it specifically indicates open-ended inclusion or membership in the so-described combination, group, series, and the like.

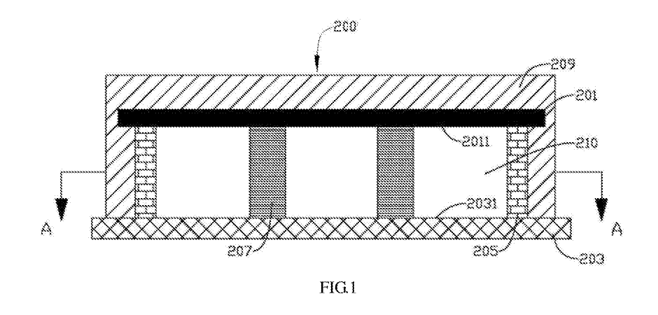

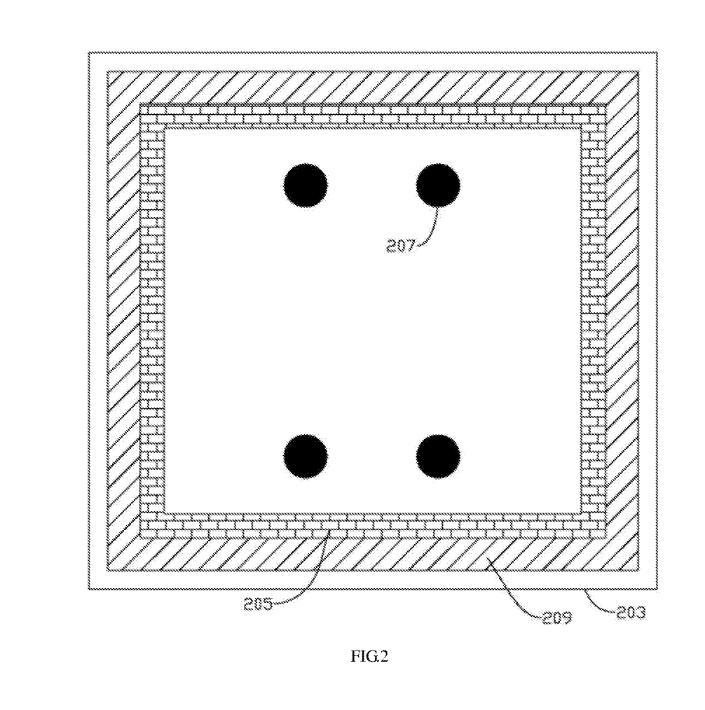

As shown in FIG. 1 and FIG. 2, a wave filter package 200 comprises a chip 201, a substrate 203, a sealed wall 205, a pillar 207, and glue 209. The chip 201 is parallel to the substrate 203, the sealed wall 205 is set up between the chip 201 and the substrate 203, and the sealed wall 205, the chip 201, and the substrate 203 are joined together so as to form a sealed chamber 210.

The chip 201 includes a first surface 2011. The substrate 203 is substantially a flat structure, the substrate 203 is provided with a second surface 2031 which is opposite to the first surface 2011.

The sealed wall 205 is a hollow column. One end of the hollow column is connected to the first surface 2011 of the chip 201 and the other end is connected to the second surface 2031 of the substrate 203. In an embodiment, the cross section of the sealed wall 205 shows four sides, the sealed wall 205 being made of copper and in contact with the substrate 203, without soldering, so long as the conductive integrity of the contact is not diminished by the glue 209.

The pillar 207 is of cylindrical shape. An end of the pillar 207 is connected to the first surface 2011 of the chip 201 and the other end to the second surface 2031 of the substrate 203. In an embodiment, there are four pillars 207, but the number of pillars is not limited. The pillar 207 is soldered on the substrate 203 for signal transmission between the chip 201 and the substrate 203.

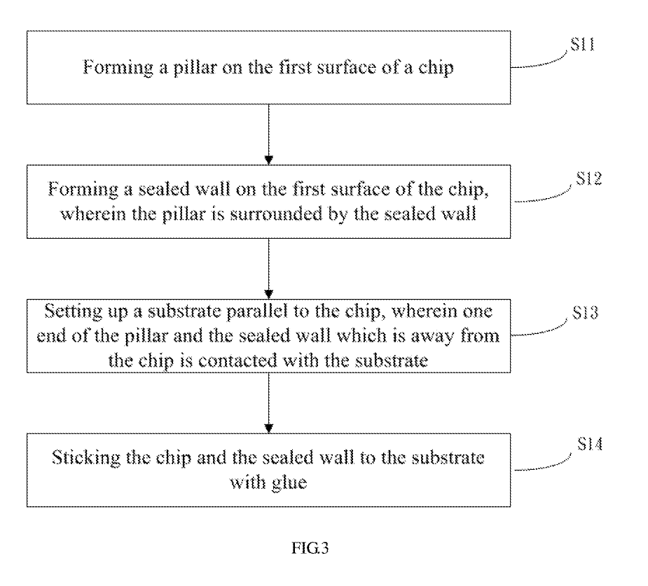

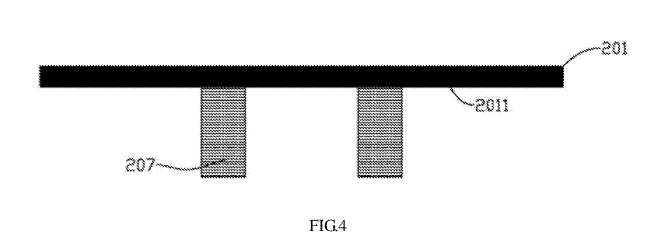

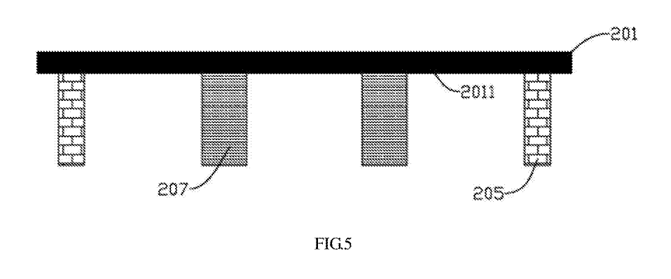

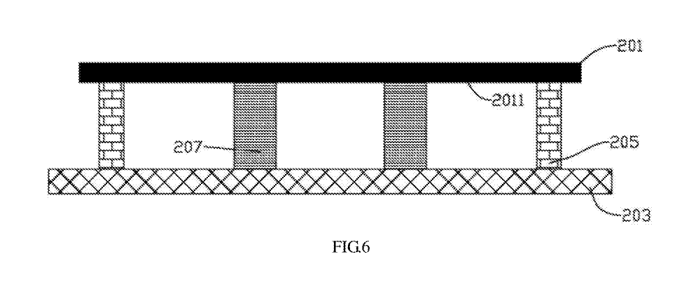

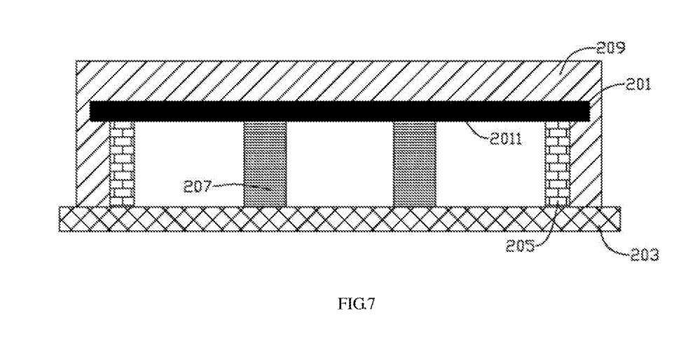

As shown in FIG. 3 to FIG. 7, the method for manufacturing wave filter package comprises the following steps.

In step S11, a pillar 207 is formed on the first surface 2011 of a chip 201. The chip 201 includes a first surface 2011, the pillar 207 is formed on the first surface 2011 by means of electroplating. The pillar 207 is cylindrical.

In step S12, a sealed wall 205 is formed on the first surface 2011 of the chip 201 by means of electroplating, the pillar 207 being surrounded by the sealed wall 205. The sealed wall 205 is a hollow column, of polygonal cross section.

In step S13, a substrate 203 is set up parallel to the chip 201. The end of the pillar 207 and the sealed wall 205 which is away from the chip 201 is soldered to and in contact with the substrate 203.

In step S14, the chip 201 and the sealed wall 205 are attached to the substrate 203 with glue 209. The glue 209 can be chosen from resin materials, such as epoxy resin.

The sealed wall 205 is set up between the chip 201 and the substrate 203 so as to form a sealed chamber 210. The nature and location of the sealed wall 205 contributes to minimize the distance of the substrate 203 and the chip 201, so that the height of the sealed wall 205 can be decreased, thereby reducing the size of the wave filter package 200.

The embodiments shown and described above are only examples. Many details are often found in the art such as the other features of an electronic wave filter. Therefore, many such details are neither shown nor described. Even though numerous characteristics and advantages of the present technology have been set forth in the foregoing description, together with details of the structure and function of the present disclosure, the disclosure is illustrative only, and changes may be made in the detail, including in matters of shape, size, and arrangement of the parts within the principles of the present disclosure, up to and including the full extent established by the broad general meaning of the terms used in the claims. It will therefore be appreciated that the embodiments described above may be modified within the scope of the claims.

What is claimed is:

1. A wave filter package comprising:
a chip;
a substrate; and
a sealed wall, wherein
the sealed wall is set up between the chip and the substrate so as to form a sealed chamber.

2. The wave filter package of claim 1, wherein the chip and the substrate are connected by at least one pillar.

3. The wave filter package of claim 2, wherein the at least one pillar is located in the sealed chamber.

4. The wave filter package of claim 1, wherein the sealed wall is made of conductive materials.

5. The wave filter package of claim 1, wherein the sealed wall is made of copper.

6. The wave filter package of claim 1, wherein the sealed wall is welding on the substrate.

7. A method for manufacturing wave filter packages, the method comprising the following steps of:
forming a pillar on the first surface of a chip;
forming a sealed wall on the first surface of the chip, wherein the pillar is surrounded by the sealed wall;
setting up a substrate parallel to the chip, wherein one end of the pillar and the sealed wall which is away from the chip is contacted with the substrate;
sticking the chip and the sealed wall to the substrate with glue.

8. The method for manufacturing wave filter packages in claim 7, wherein the pillar is welding on the substrate.

9. The method for manufacturing wave filter packages in claim 7, wherein the sealed wall is made of copper.

10. The method for manufacturing wave filter packages in claim 7, wherein the sealed wall is welding on the substrate.
